(19) United States
(12) Patent Application Publication
(10) Pub. No.: US 2008/0135882 A1
(43) Pub. Date: Jun. 12, 2008

(54) Semiconductor element

(75) Inventor: Holger Schulz, Erbach (DE)

Correspondence Address: Muncy, Geissler, Olds & Lowe, PLLC, P.O. BOX 1364, FAIRFAX, VA, 22038-1364, US

(73) Assignee: ATMEL Germany GmbH

(21) Appl. No.: 11/976,114

(22) Filed: Oct. 22, 2007

Related U.S. Application Data
(60) Provisional application No. 60/853,419, filed on Oct. 23, 2006.

(30) Foreign Application Priority Data
Oct. 21, 2006 (DE) DE 102006049740

(51) Int. Cl. H01L 23/50

(52) U.S. Cl. 257/207; 257/E23.01

(57) ABSTRACT

The invention relates to a semiconductor element (10) with an integrated circuit (12), which has at least two layers (14, 16, 18), which are electrically conductive in areas, arranged one over the other, and spaced from one another by at least one intermediate layer (24, 26), whereby in a first layer (14), trace sections (28) for providing a first voltage potential and in a second layer (16), trace sections (30) for providing a second voltage potential are provided, and with at least one protection diode (36) electrically connected to a trace section (28) of the first layer (14) and to a trace section (30) of the second layer (16), said diode which is configured to eliminate voltage peaks in a substrate layer (38) arranged beneath the first and second layer (14, 16) and which is arranged at least in part beneath a trace section.

It is provided according to the invention that the electrical connection of the protection diode (36) to the trace section (28) of the first layer (14) is realized as plated through hole (34), which penetrates the trace section (30) of the second layer (16).

Use for integrated circuits.

The present invention relates to a semiconductor element with an integrated circuit, which has at least two layers, which are electrically conductive in areas, arranged one above the other, and spaced apart from one another by at least one intermediate layer, whereby in a first layer, trace sections for providing a first voltage potential and in a second layer, trace sections for providing a second voltage potential are provided, and with at least one protection diode electrically connected to a trace section of the first layer and to a trace section of the second layer, said diode which is designed to eliminate voltage peaks in a substrate layer arranged beneath the first and second layer and which is arranged at least in part beneath a trace section.

A semiconductor element, known from the market, which is constructed conventionally on a silicon substrate acting as the carrier, has an integrated circuit, which is realized as a layer structure on the silicon substrate. The layer structure has at least two layers, which are made electrically conductive in areas and which are spaced apart by one or more intermediate layers with isolating or semiconductor properties. In this case, in a first layer, trace sections are provided for supplying a first voltage potential, for example, a supply voltage. In a second layer, trace sections are provided for supplying a second voltage potential, for example, a ground voltage.

Semiconductor elements and the integrated circuits, realized thereupon, are sensitive to voltage peaks and can be damaged or destroyed, for example, by electrostatic discharges. To protect integrated circuits from the effect of voltage peaks of this type, protection diodes, which are also called ESD protection diodes (ESD=electrostatic discharge), are looped electrically between the trace sections of the layers. With use of such protection diodes, electrostatic discharges can be removed up to a predefinable level, without damage to the integrated circuit or the semiconductor element. The diodes to be provided as ESD protection diodes in an integrated circuit must be able to remove voltages of up to 2000 V without damage and therefore require a not inconsiderable area in the layout of the integrated circuit.

The object of the present invention is to design a semiconductor element with an integrated circuit more compactly.

This object is attained according to the invention by a semiconductor element of the aforementioned type, in which the electrical connection of the protection diode to the trace section of the first layer is realized as a plated through hole, which penetrates the trace section of the second layer.

It becomes possible as a result to connect the cathode or anode of the protection diode, arranged at least partially beneath a trace section in the shortest path electrically to the trace section in the first layer. The plated through hole proceeds starting from the cathode or anode of the protection diode realized in the substrate and preferably in the perpendicular direction to the layers up to the trace section in the first layer. This shortest path is assured by an electrically isolated recess in the trace in the second layer. The recess is made in such a way that when an ESD pulse occurs within the range of an ESD specification established for the semiconductor element, no flashover between the plated through hole and the trace section of the second layer occurs. Therefore, a low-impedance connection of the protection diode to the trace section in the first layer can be realized, which assures an especially advantageous protective action by the protection diode.

The protection diode or protection diodes are realized in the substrate and at least in part directly beneath the trace sections. In other words, the protection diodes are realized at least in part beneath the integrated circuit structures that are to be protected against electrostatic discharge by the protection diodes. A projection of a trace from the first and/or from the second layer onto the substrate therefore leads to an at least partial covering with the protection diode realized in the substrate.

An especially advantageous utilization of the area beneath the traces is realized thereby, so that a greater number and/or higher dielectric strength of the protection diodes can be realized, without the area of the semiconductor element needing to be increased for this purpose or additional layers needing to be provided. It is especially advantageous when the protection diodes are realized to a overwhelming proportion, therefore to more than 70%, preferably to more than 85%, especially preferably to 100%, under the trace sections. It is possible with this type of arrangement to offer a low-impedance electrical line for incoming ESD pulses, through which a high current can flow. Penetration of the ESD pulse into the integrated circuit can be avoided thereby and the ESD resistance of the integrated circuit is increased.

An embodiment of the invention provides that the trace section for providing the first voltage potential is configured as a closed, encircling supply ring. A low-impedance connection of the first voltage potential to different areas of the integrated circuit can be realized by an encircling supply ring, which in a typically rectangular semiconductor element runs at a distance from the edge of the element and substantially parallel to the outer edges of the semiconductor element. In addition, a closed, encircling supply ring assures that occurring ESD pulses do not jump over at open ends of the trace sections to other lines of the integrated circuit and damage these. This also applies to the trace section configured as a closed, encircling supply ring for the provision of the second voltage potential.

Another embodiment of the invention provides that the plated through hole penetrates the trace section of the second layer in the area of an electrically isolated recess, which is completely surrounded by the trace section of the second layer. The plated through hole, which penetrates into the second layer of the trace section and is decoupled from the trace section by an electrically isolated recess, can be arranged especially advantageously, when it is completely surrounded by the trace section in the second layer. In other words, for the plated through hole a circumferentially closed or a recess edged circumferentially by the trace section of the second layer is provided in the trace section of the second layer, so that the plated through hole can be arranged preferably centrally in a cross section of the trace section of the second layer.

Another embodiment of the invention provides that a width of the trace section in the second layer in the area of the recess for the plated through hole is at least substantially increased by a width of the recess. This prevents that the trace section has a higher electrical resistance in the area of the recess because of a reduced cross section. The widening of the trace section in the area of the recess is preferably made such that the trace section has a substantially constant cross section over its entire length.

It is provided in another embodiment of the invention that several separate terminal pads are arranged on the edges and spaced from one another, each of which is assigned at least one diode arranged in the substrate. The terminal pads are arranged in the topmost layer and enable the electrical coupling of the integrated circuit with the use of bond wires or solder connections to a printed circuit or another semiconductor element. To realize ESD protection for the terminal pads, the terminal pads are each assigned diodes, which, however, have a lower dielectric strength than the protection diodes for the supply rings. Each terminal pad is preferably assigned at least one diode connected to the trace section of the first layer and another diode connected to the trace section of the second layer.

It is provided in another embodiment of the invention that blocking capacitors, which are looped electrically between a trace section of the first layer and a trace section of the second layer, are arranged between neighboring terminal pads. The blocking capacitors are arranged between the terminal pads, because due to the relocation of the protection diodes beneath the supply ring, space was obtained that can be utilized advantageously for the blocking capacitors.

According to another aspect of the invention, a system is provided for receiving and evaluating satellite signals, particularly a GPS system (satellite-supported global positioning system), with at least one semiconductor element according to any one of claims 1 through 8. GPS systems are typically made as mobile devices, particularly as portable devices, and profit from a compact design of semiconductor elements, which are provided in a system for receiving and evaluating satellite signals.

Other advantages and features of the invention arise from the claims and from the following description of a preferred exemplary embodiment, which is shown with the use of drawings. The figures show:

FIG. 1 a schematic plan view of a top layer of a semiconductor element,

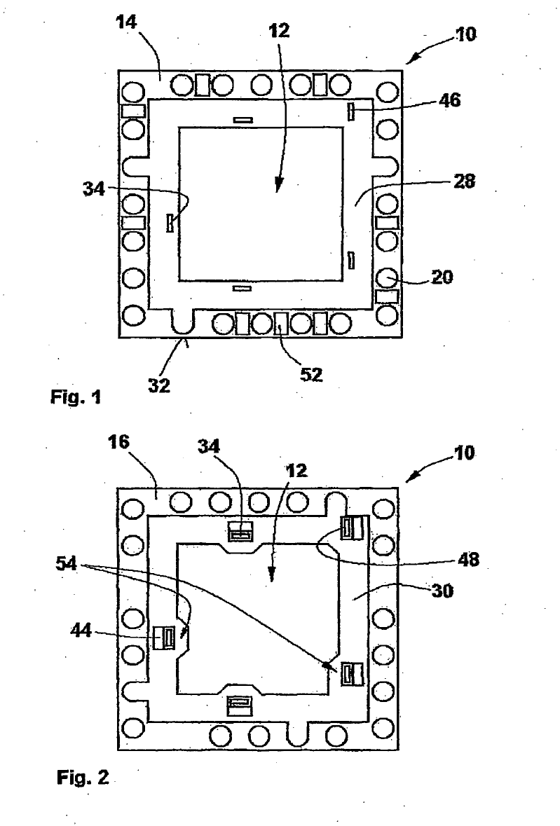

FIG. 2 a schematic plan view of a middle layer of the semiconductor element,

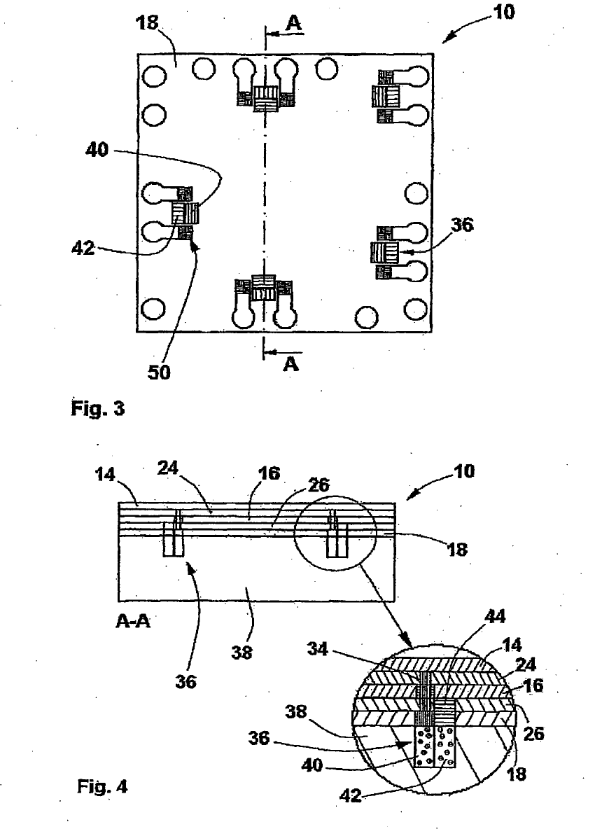

FIG. 3 a schematic plan view of a bottom layer of the semiconductor element,

FIG. 4 a cross section through the semiconductor element according to FIGS. 1 to 3.

A semiconductor element 10, shown schematically simplified in FIGS. 1 to 4, has an integrated circuit 12 not depicted in greater detail. Semiconductor element 10 can be, for example, a satellite high-frequency signal receiver circuit or RF chip, whose integrated circuit 12 is configured to receive and process a satellite frequency, established in the range greater than 1 GHz. A satellite high-frequency signal receiving circuit of this type is used in particular for satellite-supported navigation systems and emits a signal with a frequency of about 4 MHz to a satellite signal evaluation circuit to analyze the conditioned satellite signal and to provide a position and/or time and/or speed signal.

Semiconductor element 10 is realized as an example in the present case with three layers 14, 16, 18, which are arranged one over the other, spaced from one another by intermediate layers 24, 26, and electrically conductive in areas. In first layer 14, trace sections, combined into a supply ring 28, for provision of a first voltage potential, for example, a supply voltage Vcc, are provided. Supply ring 28 is configured parallel to and encircling outer edges 32 of semiconductor element 10 and is spaced from outer edges 32. Therefore, an encircling edge region between outer edges 32 and supply ring 28 is realized, in which terminal pads made as bond pads 20 are provided. A coupling or decoupling of signals or supply voltages is possible via the electrically conductive bond pads 20. Except for bond pads 20 connected directly to supply rings 28, 30, all other bond pads 20 are connected to bottom layer 18, shown in greater detail in FIG. 3, in the vertical direction downward into the drawing plane. Several bond pads 20, which assure a supplying of integrated circuit 12 with the supply voltage, are assigned to supply ring 28.

In a middle layer 16, which is shown in greater detail in FIG. 2, as in top layer 14 several trace sections are combined into a second supply ring 30, which is provided for supplying a second voltage potential, particularly a ground voltage. It is evident from FIGS. 1 and 2 that second supply ring 30 in the form of a projection of first supply ring 28 is arranged completely beneath first supply ring 28 and that some of the electrical connections, routed vertically from top layer 14 downward, from bond pads 20 are connected to second supply ring 30. To be able to assure protection of integrated circuit 12 from electrostatic discharges, coupled from outside via supply rings 28 and 30, a plurality of protection diodes, shown in greater detail in FIGS. 3 and 4, are looped electrically between first supply ring 28 and second supply ring 30.

Said protection diodes 36, which may be configured as Zener diodes, are configured—as shown in greater detail in FIG. 4—in a substrate layer 38 arranged beneath bottom layer 18 and serve to remove possible voltage peaks, as may occur during electrostatic discharges. Protection diodes 36 are arranged directly beneath supply rings 28, 30 to be able to realize an especially advantageous utilization of areas available in layers 14, 16, 18 and in substrate layer 38. Protection diodes 36 are configured in substrate layer 38 as directly adjacent p-doped and n-doped regions 40, 42. The p-doped and n-doped regions 40, 42 are electrically isolated from one another and connected to bottom layer 18, as is shown in detail in the enlarged detail in FIG. 4. Proceeding from bottom layer 18, a connection of p-doped region 40 is realized by means of a connection realized in the vertical direction between bottom layer 18 and middle layer 16. The n-doped region 42 is connected to top layer 14 proceeding from bottom layer 18 via a plated through hole 34. This electrically conductive connection between protection diodes 36 and supply ring 28 is also shown in FIG. 1 by the schematically depicted contact areas 46, adjacent from below to top layer 14 and therefore virtually invisible.

Plated through hole 34 also penetrates middle layer 16 in the area of second supply ring 30, as shown schematically in the enlarged detail in FIG. 4. In order to avoid an electrical connection between plated through hole 34 and second supply ring 30, an encircling, isolating edge 48, shown schematically in FIG. 2, is configured around plated through hole 34. Connections 44, proceeding from p-doped region 40 and bordering middle layer 16 from below, are also indicated in FIG. 2.

Diodes 50, shown in greater detail in FIG. 3, realized like protection diodes 36 with their p-doped and n-doped regions in substrate layer 38, and provided for blocking unwanted voltage peaks, are assigned to bond pads 20.

Blocking capacitors 52, which are realized in areas in top layer 14 and in middle layer 16 and provided, for example, for stabilizing input signals applied at the bond pads, are provided between bond pads 20. The blocking capacitors can be arranged by the advantageous arrangement of protection diodes 36 between bond pads 20, so that an especially advantageous blocking effect can be achieved.

Corresponding widened areas 54 are created in supply ring 30 in each case in the area of plated through holes 34 to assure that a cross section of second supply ring 30 despite plated through hole 34 is substantially constant. In the embodiment shown in FIG. 2, widened areas 54, inwardly projecting from supply ring 30, are provided in each case in the areas of plated through holes 34. In other embodiments of the invention, which are not shown, it can also be provided that the widended area extends outwards in the direction of the outer edge or a proportional inwardly and outwardly widened area is provided.

### LIST OF REFERENCE CHARACTERS

### Description

10 semiconductor element
12 integrated circuit
14 top layer
16 middle layer
18 bottom layer
20 bond pads
- - -
24 first intermediate layer
26 second intermediate layer
28 supply ring (VCC)
30 supply ring (GND)
32 outer edge of semiconductor element
34 plated through hole
36 protection diodes
38 substrate layer
40 p-doped region
42 n-doped region
44 connection
46 contact area
48 isolating edge
50 diodes
52 blocking capacitors
54 widened area

1. Semiconductor element (10) with an integrated circuit (12), which has at least two layers (14, 16, 18), which are electrically conductive in areas, arranged one over the other, and spaced from one another by at least one intermediate layer (24, 26), whereby in a first layer (14), trace sections (28) for providing a first voltage potential and in a second layer (16), trace sections (30) for providing a second voltage potential are provided, and with at least one protection diode (36) electrically connected to a trace section (28) of the first layer (14) and to a trace section (30) of the second layer (16), said diode which is designed to eliminate voltage peaks in a substrate layer (38) arranged beneath the first and second layer (14, 16) and which is arranged at least in part beneath a trace section (28, 30), characterized in that the electrical connection of the protection diode (36) with the trace section (28) of the first layer (14) is realized as a plated through hole (34), which penetrates the trace section (30) of the second layer (16).

2. Semiconductor element according to claim 1, characterized in that the trace section (28) for providing the first voltage potential is configured as a closed, encircling supply ring.

3. Semiconductor element according to claim 1 or 2, characterized in that the trace section (30) for providing the second voltage potential is configured as a closed, encircling supply ring.

4. Semiconductor element according to claim 1, 2, or 3, characterized in that the plated through hole (34) penetrates the trace section (30) of the second layer (16) in the area of an electrically isolated recess, which is completely surrounded by the second layer (16).

5. Semiconductor element according to claim 4, characterized in that a width of the trace section (30) in the second layer (16) in the area of the recess for the plated through hole (34) is at least substantially increased by a width of the recess.

6. Semiconductor element according to claim 5, characterized in that a cross section of the supply ring (28, 30) is substantially constant.

7. Semiconductor element according to any one of the preceding claims, characterized in that several separate terminal pads (20) are arranged on the edges and spaced from one another, each of which is assigned at least one diode (50) arranged in the substrate.

8. Semiconductor element according to any one of the preceding claims, characterized in that blocking capacitors (52), which are looped electrically between a trace section (28) of the first layer (14) and a trace section (30) of the second layer (16), are arranged between neighboring terminal pads (20).

9. System for receiving and evaluating satellite signals, particularly a GPS system, with at least one semiconductor element (10) according to any one of claims 1 through 8.
